(19) United States
(12) Patent Application Publication
(10) Pub. No.: US 2005/0076172 A1
(43) Pub. Date: Apr. 7, 2005

(54) Architecture for static frames in a stack machine for an embedded device

(75) Inventor: James P. Caska, Glebe (AU)

Correspondence Address: DARBY & DARBY P.C., P. O. BOX 5257, NEW YORK, NY, 10150-5257, US

(73) Assignee: Infology Pty Limited dba/Muvium.com, Glebe (AU)

(21) Appl. No.: 10/893,753

(22) Filed: Jul. 16, 2004

(30) Foreign Application Priority Data
Jul. 16, 2003 (AU) 2003903652

(51) Int. Cl. G11C 5/00

(52) U.S. Cl. 711/1; 718/1

(57) ABSTRACT

A method for representing the Stack Frame of a Stack Machine such as the Java Virtual Machine and associated software algorithms that significantly improves the performance of the Stack Machine processing device. By placing the Stack frame of the Stack Machine in known static locations instead of defining it in a referenced location in data heap memory, several important optimizations can be realized by an enhanced Java Virtual Machine compiler which result in significant performance improvements.

### CROSS-REFERENCE TO RELATED APPLICATIONS

This Utility Application is a continuation-in-part of an Australian Provisional Application Number 2003903652, which was previously filed on Jul. 16, 2003, the benefit of the earlier filing date is hereby claimed under 35 U.S.C. 119.

### FIELD OF THE INVENTION

The present invention relates generally to a compiler for a virtual machine and more particularly to improving performance with an enhanced virtual machine compiler.

### BACKGROUND OF THE INVENTION

A Stack Machine such as the Java Virtual Machine (JVM) defines a Stack Frame in which it stores a logical operand stack and local variables for the bytecode instructions to operate against. The JVM describes the frame as existing on the Heap and where the stack frame is stored and accessed by reference pointer schemes. The stack is employed as a Virtual Stack and is considered an abstract concept.

For a Stack Machine on a 32 bit processor, a relatively simple operation might be the bitwise OR of 2×32 bit numbers.

Referring to the pseudo code segment below and FIG. 1. The implementation of an OR Stack machine operator is relatively straight forward for a 32 bit computing device.

Step 1: Push LocalVariable 0 on to the Stack.

Step 2: Push Literal Value 2 onto the Stack.

Step 3: Add two stack operands together by popping two values off the stack OR'ing them and pushing the resultant value back onto the stack.

Or( ){

push(pop( ) | pop( ))

}

For a Stack Machine on an eight bit processor, the implementation can be more complex when it attempts to represent a higher order data value on the stack because of the fragmentation of the data value over several ‘slot's in the stack. See FIG. 2. In a stack implementation of such a stack operator, it first pop( )'s the eight operands and stores them as local variables before performing the computation and then pushing the result back onto the stack. An exemplary code segment is presented below.

Or( ){

byte b_msb = pop( );
byte b_2 = pop( );
byte b_1 = pop( );
byte b_lsb = pop( );
byte a_msb = pop( );
byte a_2 = pop( );
byte a_1 = pop( );
byte a_lsb = pop( );
push( a_lsb | b_lsb);
push( a_1 | b_1);
push( a_2 | b_2);
push( a_msb | a _msb);

}.

### BRIEF DESCRIPTION OF THE DRAWINGS

FIGS. 1-4 show block diagrams of the architecture and data flow for a virtual machine; and

FIGS. 5-13 illustrate block diagrams of the inventive architecture and inventive data flows in accordance with the invention.

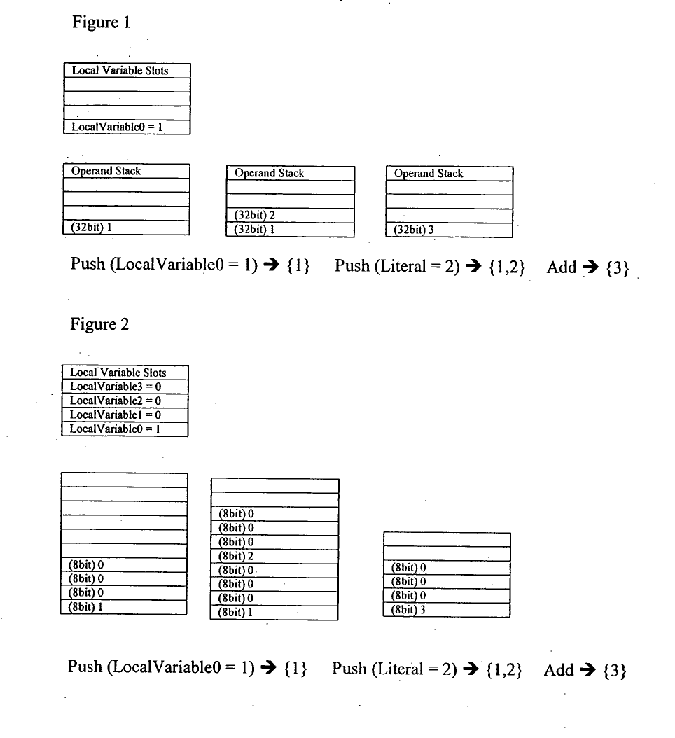

### DETAILED DESCRIPTION OF THE INVENTION

In the following detailed description, reference is made to the accompanied drawings in which are shown specific exemplary embodiments of the invention. These embodiments are described in sufficient detail to enable those skilled in the art to practice the invention, and it is understood that other embodiments may be utilized, and other changes may be made, without departing from the spirit or scope of the invention. The following detailed description is, therefore, not to be taken in a limiting sense, and the scope of the invention is defined only by the appended claims.

The present invention is directed to a method, system and apparatus for optimizing the performance of an implementation of a stack machine computing device such as a Java Virtual Machine in extreme resource limited 8-bit microprocessors, microcontrollers, and the like, that support direct addressing of their data memory.

Stack machine computing devices such as Java Virtual Machine define their computing operations with respect to a Virtual Stack and the instructions of computing device are specified Stack Transforms. An example of this is the Java Virtual Machine bytecode instruction set or the Microsoft .NET MSIL instruction set. Due in part to the dependence on accessing the virtual stacks, the computing performance of a computing device implementing such a stack machine stack is dependent on the speed it can access the stack. 32 and 64 bit processors are typically architected for relative address and stack operations and where the internal data representation such as a 32 bit integer is the same or greater size virtual stack and stack operations accessing a virtual stack has only a small overhead and is generally not a performance limitation in such implementations.

However, for an 8-bit microcontroller, microprocessor, and the like, implementing a Stack Machine, the stack access can become a significant bottle-neck due to the limited facilities for relative addressing mode and where the datatypes representing the operands of the stack machine are of a higher order, e.g., 16, 32, 64 or more bits, than the internal 8 bit internal data operations and hence require multiple relative addressing configurations per operation.

Many microcontroller architectures have a load/store architecture and have a relatively small number of working registers. The typically access their data memory using relative addressing and offer limited direct addressing to their data memory. Other microcontroller architectures can offer direct addressing to the entire data memory using a register banking scheme.

For those architectures offering direct addressing to a sufficient number of registers, the present invention offers techniques for substantial performance optimization by a series of pre-computing techniques which compute the direct locations of registers participating in a stack operation and operate directly on these registers leading to significant performance gains per operation. A second aspect to the present invention is a ‘peep-hole’ optimization technique which groups a series of stack operations and computes the final result into their final direct locations without accessing the stack. This aspect can lead to substantial further performance gains.

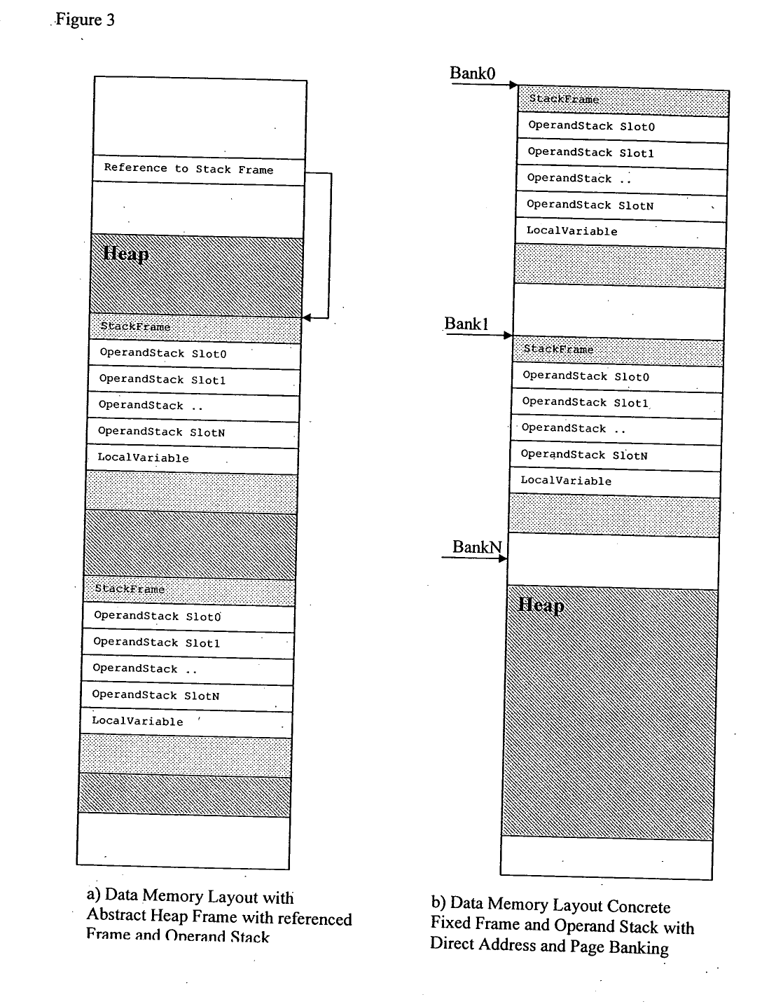

The present invention refers to an inventive technique for representing the Stack Frame of a Stack Machine such as the Java Virtual Machine and associated software algorithms that significantly improve the performance of the Stack Machine processing device. Referring to FIG. 3, the present invention recognizes that for computing devices that support direct addressing of their data memory placing the Stack frame of the Stack Machine in known static locations instead of defining it in a referenced location in data heap memory, several important optimizations can be realized by an enhanced Java Virtual Machine compiler which result in significant performance improvements.

The first aspect of the invention takes advantage of the known locations of Stack Frame operand Stack register slots. Referring to FIG. 3, and the code segment below, the frame operand stack slots are pre-computed and as a compiler option replaced with equivalent inline code that directly address the operands and resultant slots. A key consequence of this form of optimization is that accessing the Operand Stack is not required nor is the overhead of calling the function that implement the Stack Machine instruction. This optimization has been found to yield in many cases an order of magnitude performance improvement.

| If optimiseThisBytecode( )){ | | |
|---|---|---|
| MOVF | slot_4, W | ;8 Instructions |
| IORWF | slot_0, F | |
| MOVFslot_5, W | | |
| IORWF | slot_1, F | |
| MOVFslot_6, W | | |
| IORWF | slot_2, F | |
| MOVFslot_7, W | | |
| IORWF | slot_8, F | |
| else | | |
| CALL OR | | ;Stack operation version |

End if

The second aspect of the invention further enhances performance by recognizing the opportunity to compute the outcome of a group of several bytecodes in sequence as a single inline optimization. Whereby patterns of bytecodes are recognized and optimal inline code is computed to operate directly on the known slot locations for the entire sequence of bytecodes. An important consequence is that replacing several bytecodes with a short inline sequence both dramatically improves performance and reduces the code size compared to implementing each bytecode individually.

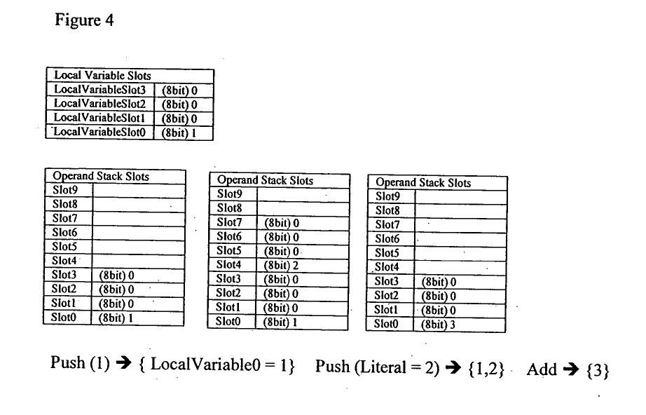

To illustrate this technique, referring to FIG. 4 and the code segment below, the three stack operations are utilized.
Push(LocalVariable)
Push(LiteralValue)
OR

In a static scheme, the LocalVariable slots are known to be at fixed static location, the Literal Value is known by the complier at compile time and the OR operator resultant is inserted at known operand stack locations. Hence this pattern can be recognized at compile time and an optimal code sequence inserted to replace all three bytecodes.

| If(optimisePattern( LocalPush, LiteralPush, Or)){ | | |
|---|---|---|
| MOVF | localvariable_slot_0, W | ;variable0 |
| IORLW | 2 | |
| MOVWF | slot_0 | |
| MOVF | localvariable_slot_1, W | |
| IORLW | 0 | ;IORLW 0 may be ignored in |
| | | optimal |
| MOVWF | slot_0 | ;implementation |
| MOVF | localvariable_slot_2, W | |
| IORLW | 0 | ;IORLW 0 may be ignored in |
| | | optimal |
| MOVWF | slot_1 | ;implementation |
| MOVF | localvariable_slot_3, W | |
| IORLW | 0 | ;IORLW 0 may be ignored in |
| | | optimal |
| MOVWF | slot_2 | ;implementation |
| }else{ | | |
| call | pushLocalVariable | |
| call | pushLiternalValue | |
| call | or | |

}

In a traditional referenced stack frame accessing a new frame is a straightforward task of switching the address location to point to a new stack frame to operate within. This approach requests an allocated block of memory from a memory manager such as the heap which creates a block of memory and clears it returning a reference to this block which is stored the reference to this block. In the static frame technique a backup of the frame is made by copying the current frame to a known location before commencing execution in the new frame.

A fourth aspect of the present invention is to take advantage of this copying stage to compress the frame as it is copied. A consequence of this compression stage is that the static frame can be maximally sized without the penalty of using unnecessary critical memory resources. 8-bit computing devices that enable direct access to their registers typically employ a banking scheme to allow access to a greater number of registers that are implied by their internal 8 bit datatype.

A fifth aspect of the present invention is to take advantage of this banking scheme to create one or more Frame caches. By aligning the static frames in the same location on each banked page, frames can be switched between by changing the current bank. A frame cache is a pre-allocated frame on an alternative page. If the frame cache is available, the bank is switched and execution begins on the new frame. However, if the cache page is not available, a frame is backed up and optionally compressed. Caching frames in this way reduces the need to backup frames to memory. The frame cache may be arranged as deep as the number of pages available.

Many Stack Machine computing devices such as the Java Virtual Machine support execution threads. A sixth aspect of the present invention is to implement threads by having threads execute in their own Frame page. Context switching between threads in this scheme is performed by switching the memory bank to the bank that contains the Frame Stack occupied by the state of the current thread. The number of threads supported with fast context switching may be as many as the number of banked pages available.

Terms

Stack: The stack is a logical LIFO (Last In First Out) stack onto which data is pushed and popped. Stack Machines are described in terms of their operations over the Stack.

Bytecode: The machine code of a Stack Based Virtual Machine language such as Java Bytecode or Microsoft MSIL code. Bytecode functionality is defined in terms of its effect on the Stack and defines a pre-condition for what the stack should be before it executes and a post condition for that the stack should be after it executes.

Vbytecode: A Virtual Bytecode which is the internal representation of a one or more Bytecode. A Virtual Bytecode is functionally equivalent to one or more Bytecodes and can be used interchangeably. The pre condition of a VBytecode is equal to the pre-condition of the first Bytecode in the equivalent Bytecode sequence. The post-condition of a VBytecode is equal to the post-condition of the final Bytecode in the equivalent VBytecode sequence.

Bytecode Stack→State Transform Compiler

| | |
|---|---|
| Input: | Bytecode Files |
| Output: | Native Code |

As shown in FIG. 5, the Stack→Stack Transform compiler compiles Bytecode programs into native programs for execution on a specific device. The compiler first parses the Bytecode program into a stream of individual Bytecodes, then transforms and compresses the Bytecode stream into VBytecode equivalent representation replacing where recognised sequences of Bytecodes with equivalent Virtual Bytecodes or VBytecodes. The set of VBytecodes is a superset of the set of Bytecodes. The program execution of the VBytecode stream is then virtualised to keep track of the virtual stack for all execution pathways, by tracking branching and target labels and saving a restoring the virtual trace stack, the stack remains valid even though the code does not follow execution branches but continues sequentially. Finally, the code generator for the VBytecode is accessed and native code for the VBytecode is generated with respect to the absolute addresses for the stack locations accessed through the current stack state. The native code generated is appended to the native program. Once all Bytecodes have been processed, the Bytecode to native code transform is complete.

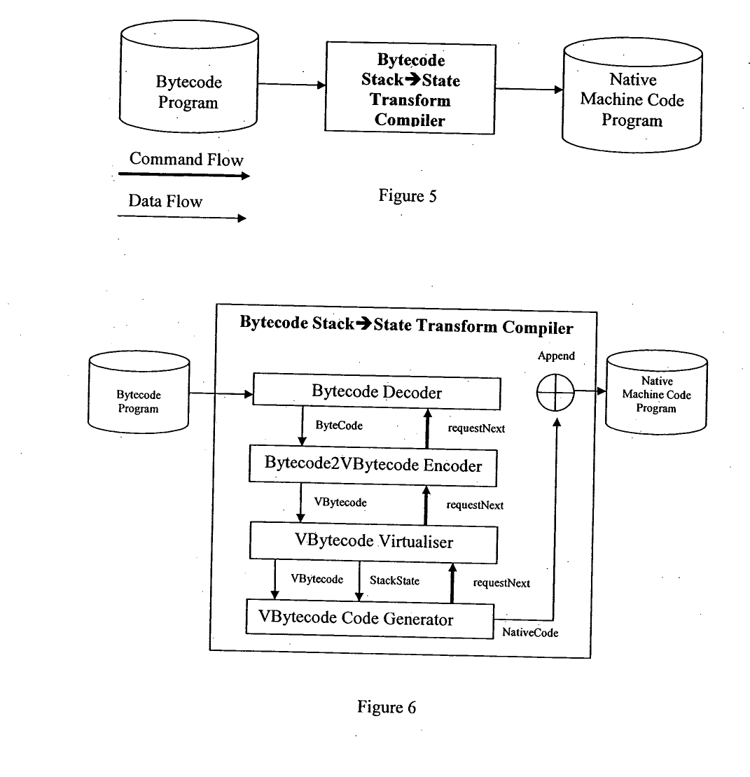

Referring to FIG. 6, the Compiler consists of at least four components
1. Bytecode Decoder
2. Bytecode: VBytecode Encoder
3. VBytecode Virtualizer
4. VBytecode Code Generator

Bytecode Decoder

| | |
|---|---|
| Input: | InputStream |
| Output: | Bytecodes |

The Bytecode decoder performs the task of parsing a Bytecode encoded InputStream into individual Bytecodes and storing them in a Buffer to be issued upon request.

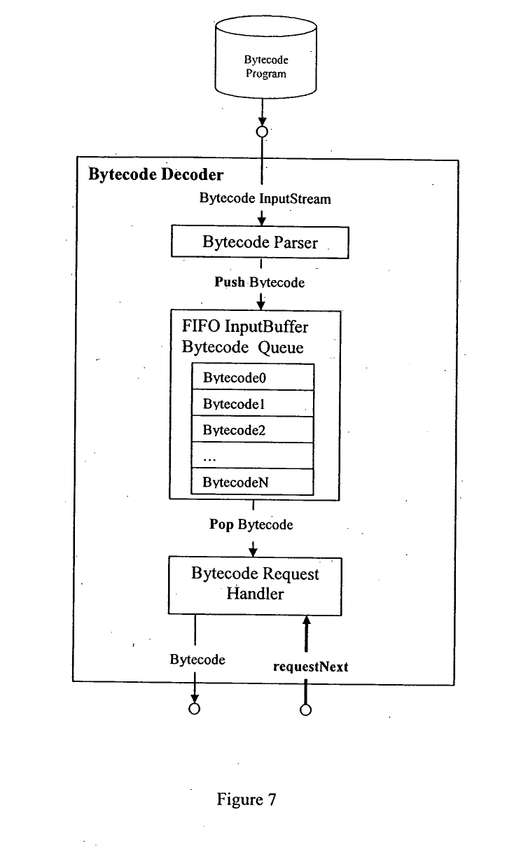

Referring to FIG. 7, the Bytecode Decoder consists of at least the following components:
1. Bytecode Parser
2. FIFO InputBuffer Bytecode Queue
3. Bytecode Request Handler

Bytecode Parser

| | |
|---|---|
| Input: | InputStream |
| Output: | Bytecodes |

The Bytecode Parser performs the task of extracting Bytecodes from an InputStream of data and pushing the resulting Bytecodes into a FIFO Queue. The InputStream is a representation of the file format of the Bytecode file. For example, java Bytecode is stored in a well defined and public class file format. The InputStream is parsed according to this format and the resulting Bytecodes are pushed into the Buffered Queue.

FIFO InputBuffer Bytecode Queue

| | |
|---|---|
| Input: | Bytecodes |
| Output: | Bytecodes |

The InputBuffer Bytecode Queue performs the task of buffering Bytecode output from the Bytecode parser ready for pulling downstream. The Queue is implemented as a FIFO Queue with push and pop operators.

Bytecode Request Handler

| | |
|---|---|
| Input: | IssueRequest |
| Output: | Bytecodes |

The Bytecode Request Handler performs the task of issuing Bytecodes from the FIFO InputBuffer Bytecode Queue. If the buffer becomes empty it is responsible for prompting the Bytecode parser to fill the buffer if further Bytecodes are available. The Request handler receives requests for Bytecodes and issues one Bytecode per request to the downstream requester.

Bytecode2VBytecode Encoder

| | |
|---|---|
| Input: | Bytecodes |
| Output: | VBytecodes |

The Bytecode2VBytecode Encoder performs the task of compressing a stream of Bytecodes in a smaller stream of equivalent VBytecodes. Each VBytecode is functionally equivalent to a sequence of one or more Bytecodes. The Bytecode2VBytecode Encoder recognises these sequences and inserts the equivalent VBytecode into the stream. If no VBytecode is available the original Bytecode remains in the stream. Since the set of VBytecodes is a superset of the set of Bytecodes this is a unity transform. The resulting VBytecode is then pushed into an FIFO Output Buffer ready to be issued to downstream VBytecode requests.

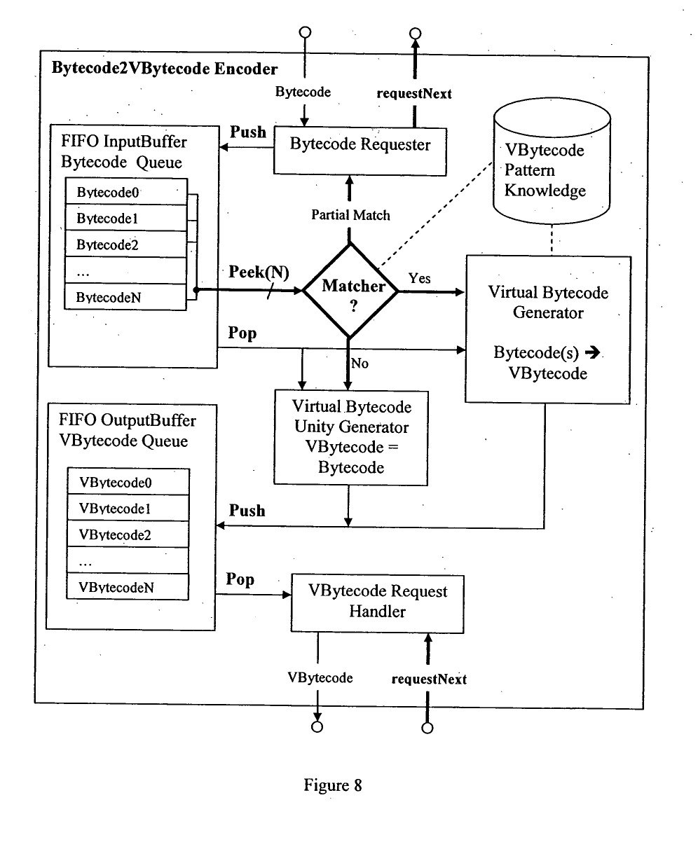

Referring to FIG. 8, the Bytecode2VBytecode Encoder includes the following components:
1. Bytecode Requester
2. FIFO InputBuffer Bytecode Queue
3. Matcher
4. Virtual Bytecode Generator
5. Virtual Bytecode Unity Generator
6. FIFO Output Buffer Queue
7. VBytecode Request Handler

Bytecode Requester

| | |
|---|---|
| Input: | Bytecodes |
| Output: | Bytecodes |

The Bytecode requester performs the task of requesting Bytecodes and pushing them into the FIFO InputBuffer Bytecode Queue. Two conditions will cause the Bytecode Requestor to request and push a Bytecode into the FIFO InputBuffer Bytecode Queue. The first condition is where the FIFO InputBuffer Bytecode Queue has become empty and the second condition is where the VBytecode Matcher has recorded a partial match but requires additional Bytecodes.

FIFO InputBuffer Bytecode Queue

| | |
|---|---|
| Input: | Bytecodes |
| Output: | Bytecodes |

The InputBuffer Bytecode Queue performs the task of buffering Bytecodes for analysis by the Matcher. In addition to the push and pop operators, a peek operator that can access all the VBytecodes in the buffer is utilized by the matcher when analysing Bytecode sequences.

Matcher

| | |
|---|---|
| Input: | Bytecode[s] |
| Output: | Match, Not Matched, Partial Match control signal |

The Matcher performs the task detecting if there is an equivalent VBytecode available to replace a sequence of Bytecodes. The pattern matcher inspects the sequence of Bytecodes available in the InputBuffer and matches the pattern with a knowledge base of VBytecode equivalent patterns. The present Bytecode sequence will match, not match or match partially. When matched control is passed to the Virtual Bytecode Generator which creates a new VBytecode from the matched sequence. When not matched control is passed to the VBytecode Unity Generator which creates a new VBytecode from the topmost Bytecode. When partially matched a further Bytecode is requested from the Bytecode requester and the match is repeated with the additional information.

Virtual Bytecode Generator

| | |
|---|---|
| Input: | Bytecode[s] |
| Output: | VBytecode |

The Virtual Bytecode generator performs the task of transforming a sequence of Bytecodes into a single VBytecode. The Bytecode sequence is popped from the InputBuffer and the necessary parameters are extracted from the Bytecodes from which a new equivalent VBytecode is constructed. The VBytecode is then pushed into the OutputBuffer. The outcome of this is to reduce the total number of equivalent Bytecodes that require processing.

Virtual Bytecode Unity Generator

| | |
|---|---|
| Input: | Bytecode |
| Output: | VBytecode |

The VBytecode Unity Generator is performs the task of transforming a single Bytecode into its equivalent VBytecode form. The set of Bytecodes is a subset of the set of VBytecodes. The VBytecode is then pushed into the OutputBuffer.

FIFO OutputBuffer VBytecode Queue

| | |
|---|---|
| Input: | VBytecode |
| Output: | VBytecode |

The FIFO OutputBuffer Bytecode Queue performs the task of buffering VBytecodes for later issuing on request

VBytecode Request Handler

| | |
|---|---|
| Input: | IssueRequest |
| Output: | VBytecode |

The VBytecode request handler performs the task of issuing VBytecodes from the FIFO OutputBuffer Bytecode Queue. The Request handler receives requests for VBytecodes and issues one VBytecode per request to the downstream requester.

VBytecode Virtualizer

| | |
|---|---|
| Input: | VBytecodes |
| Output: | StackState, VBytecode |

The VBytecode Virtualizer performs the task of maintaining the state of the stack for each Bytecode instruction as if the code was actually executing. However, VBytecodes are delivered sequentially where a real program branches at various points in the code sequence hence to maintain the stack correctly involves maintaining several stack states. When a branch occurs to an alternative location, the current state of the stack is cloned and stored against the target label of the branch. When that branch label is later entered, the state of the stack is restored to that of the branch to simulate real-code execution. It is assumed that the state of the stack is symmetrical and that any code sequence entering a label will have the same stack. This assumption enables the stack machine program to build a stable application. Code that does not adhere to this assumption can be rejected as an invalid program. The VBytecode Virtualisation technique is somewhat similar to the JAVA validation technique in some ways and different in other ways. In particular, the invention's goal is to track the literal addresses implied by the stack state with respect to the static frames, the variable data-type sizes associated with the highly resource constrained implementation of the JVM, and the extended VBytecode model.

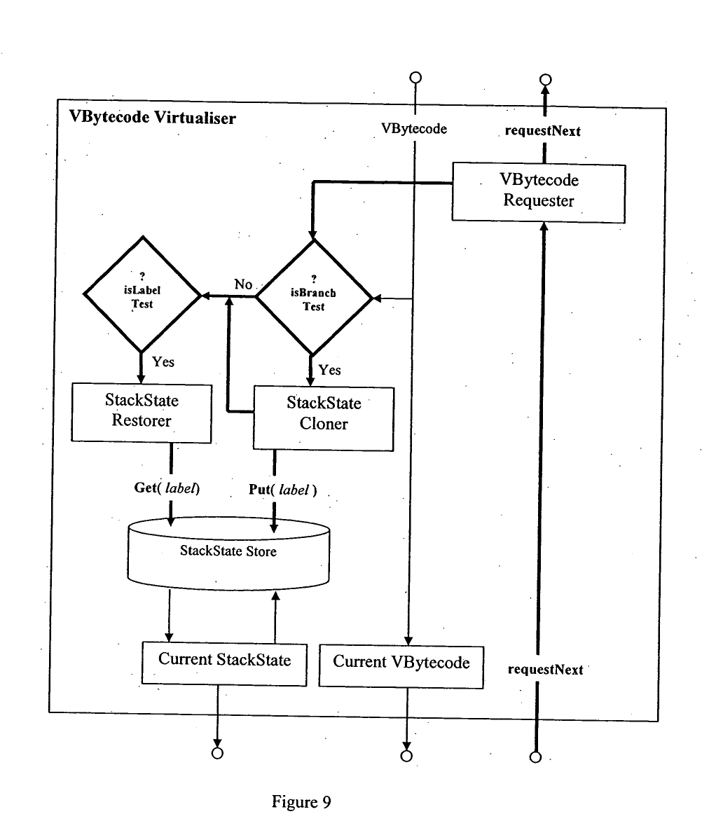

Referring to FIG. 9, the VBytecode Virtualizer consists of the following components:
1. VBytecode Requester
2. StackState Restorer
3. StackState Cloner
4. StackState Store
5. Current StackState
6. Current VBytecode

VBytecode Requester

| | |
|---|---|
| Input: | VBytecodes, RequestSignal |
| Output: | VBytecodes |

The VBytecode requester performs the task of forwarding the request for the next VBytecode and setting the Current VBytecode to the retrieved VBytecode. Once a VBytecode has been retrieved the VBytecode Requester has the further responsibility of issuing a Stack analysis control signal to perform stack trace maintenance operations.

StackState Restorer

| | |
|---|---|
| Input: | VBytecode |
| Output: | Set Current StackState |

The StackState Restorer has the task of determining if a VBytecode is a label, a label is a VBytecode that is a destination for a branch VBytecode. If it is a label, then a StackState is retrieved from the StackState Store and the Current StackState is set with this StackState.

StackState Cloner

| | |
|---|---|
| Input: | VBytecode |
| Output: | Clone Current StackState |

The StackState Cloner has the task of determining if a VBytecode is a branch. A branch is a VBytecode that under some conditions will jump to a VBytecode other than the next sequential VBytecode for execution. If it is a branch then the Current StackState is cloned and stored in the StackState Store using the branch target label or labels as the key.

StackState Store

The StackState Store has the task of storing and retrieving StackStates to and from the Current StackState using a target label as the access key

Current StackState

The Current StackState has the task of holding the Current StackState which is exposed for use by VBytecode code generators and for copying to and from the StackState Store.

Current VBytecode

The Current VBytecode has the task of holding the Current VBytecode which is exposed for use by VBytecode generators.

VBytecode Code Generator

| | |
|---|---|
| Input: | Current StackState, Current VBytecode |
| Output: | Native code |

The VBytecode Code Generator performs the task of generating native code from VBytecodes. The Current VBytecode is used to retrieve a Code Generator from a VBytecode code generator database. The Code Generator uses the Current StackState to retrieve the static addresses parameters which are used to generate dynamic code operating directly on those addresses. The output native code may then be appended to a native program. Once the code is generated, the VBytecode executes the pre and post conditions of its execution on the Current StackState synchronising the StackState. This is repeated for all VBytecodes to be processed.

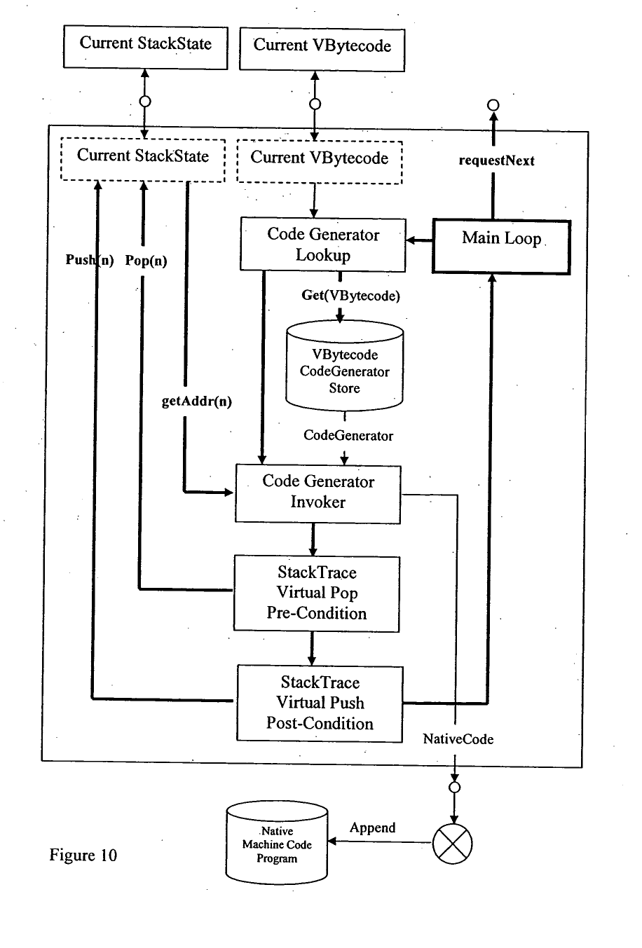

Referring to FIG. 10 the VBytecode Code Generator includes the following components.
1. Code Generator Lookup
2. VBytecode Code Generator Store
3. Code Generator Invoker
4. StackTrace Virtual Pop Pre-Condition
5. StackTrace Virtual Push Post-Condition

Code Generator Lookup

| | |
|---|---|
| Input: | Current VBytecode |
| Output: | VBytecode Code Generator |

The Code Generator Lookup performs the task of retrieving a code generator from the VBytecode Code Generator Store using the Current VBytecode as the retrieval key.

VBytecode Code Generator Store

The VBytecode Code Generator Store performs the task of retrieving a VBytecode Code Generator using a VBytecode key.

Code Generator Invoker

| | |
|---|---|
| Input: | VBytecode Code Generator |
| Output: | Native code |

The Code Generator Invoker performs the task of invoking a VBytecode Code Generator, passing it the Current StackState and directing the resulting native code output.

StackTrace Virtual Pop Pre-Condition

| | |
|---|---|
| Input: | VBytecode Code Generator |
| Output: | StackState Pop(s) |

The StackTrace Virtual Pop Pre-Condition performs the task of popping the operands from the Current Stack that were used by the VBytecode. Each VBytecode has a pre condition defined for the data elements that it consumes from the Stack during its execution.

StackTrace Virtual Push Post-Condition

| | |
|---|---|
| Input: | VBytecode Code Generator |
| Output: | StackState Push(s) |

The StackTrace Virtual Push Post-Condition performs the task of pushing operands onto Current Stack that are the outputs from the VBytecode. Each VBytecode has a post condition defined for the data elements that it consumes from the Stack during its execution.

Frame Compressor

The Frame Compressor performs the task of compressing a frame into a compressed representation. Frame compression is important on highly resource constrained devices as it allows the static frame to be maximally sized yet consume only minimal resources when actually pushed onto the heap by deep method calls. Any compression technique can be used however it is very important that the compression technique be very fast and very code compact due to the highly constrained execution target environment. It should also be suitable for hardware implementation. One suitable implementation takes advantage of the sparseness of a maximally sized frame to remove the Zero's. This involves maintaining a Bitvector header which stores the positions of zero's in the original frame and copies only the non-zero data. For typical applications this results in a 60-70% compression rate yet is very efficient to implement.

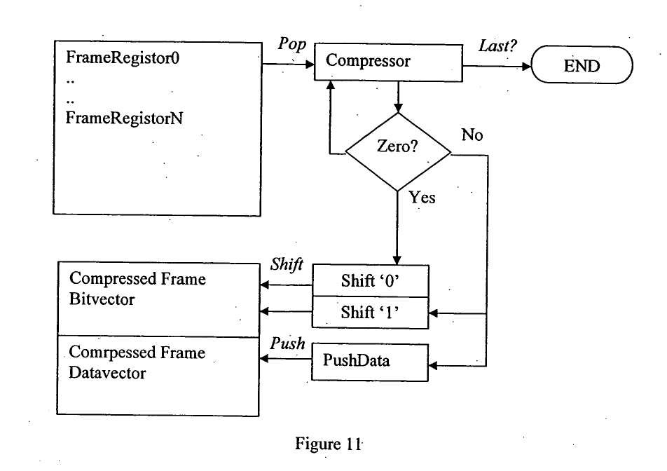

Referring to FIG. 11, the frame compressor includes the following components
1. Frame Registers
2. Compressor
3. Bitvector Shifter
4. Compressed Frame Bitvector
5. Compressed Frame Datavector
   Frame Registers

The Frame registers are the original frame to be compressed. They are a sequential block of N data registers. A pop operator iterates through the data sequentially

Compressor

The compressor pops Frame Register data, if the data is non zero it invokes the Bitvector Shifter with value 1 and copies that data by pushes the data into the Compressed DataStore. If the data is zero it invokes the Bitvector Shifter with value 0 but does no copy operation

BitVector Shifter

The BitVector shifter is responsible for shifting 1's and 0's into a Bitvector sequence of registers.

Compressed Frame Bitvector

The compressed Bitvector is a sequence of registers FrameRegisterSize/RegisterBitSize in length. The bitvector is a sequence of bits which are shifted as a block.

Compressed Frame Datavector

The compressed Datavector is the a dynamic sequence of registers into which the non-zero valued Frame Registers are copied

Frame Decompresser

The Frame Compressor performs the task of decompressing a compressed frame by reversing the frame compression algorithm.

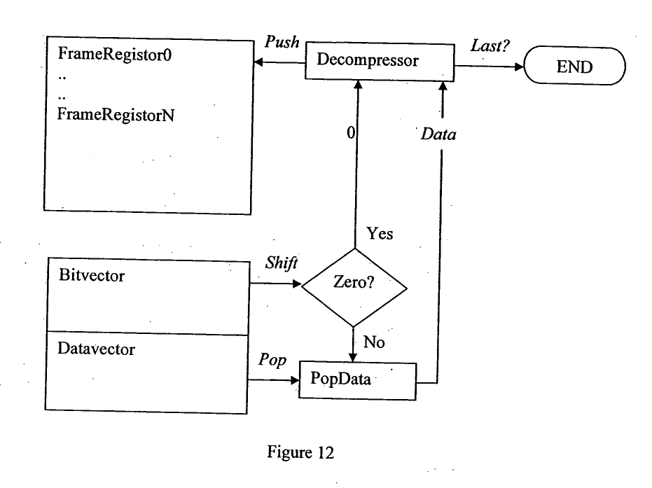

Referring to FIG. 12, the frame compressor consists of the following components.
1. Frame Registers
2. Compressor
3. Bitvector Shifter
4. Compressed Frame Bitvector
5. Compressed Frame Datavector
   Frame Registers

See Frame Compressor, Frame Registers

Decompressor

The Decompressor shifts out a bit from the Compressed Frame Bitvector. If the Bit is 1 then a data register is popped from the Compressed Frame DataVector and pushed into the Frame Register. If the Bit is 1 then a zero 0 is pushed into the Frame Register. The order of the push and pop of the Compressor and Decompressor is reversed so as to ensure the Frame is restored to contain the original data.

Bitvector Shifter

See Frame Compressor, Bitvector

Compressed Frame Bitvector

See Frame Compressor, Compressed Frame Bitvector

Compressed Frame Datavector

See Frame Compressor, Compressed Frame Datavector

Device within Device Emulation For Cross Platform Execution Of Real-Time Java Virtual Machine

One of the advantages of the Java Virtual Machine is its platform independent execution. One approach to cross platform portability is to maintain the source code of a java virtual machine interpreter in a high level language such as ‘C’ or ‘C++’ and compile for the target processor. However, the performance of interpretive Java Virtual Machines can be too slow for many real-time applications.

The availability of the Stack→State Transform compiler for highly resource constrained computing devices has realized the performance needed for real-time applications however the task of building individual code generators for all possible computing architectures can be overwhelming.

The present invention involves a technique for emulating the minimal device requirement required by the inventive enhanced JVM execution on larger devices which by doing so become enabled for executing high performance java code with only a minimal execution performance penalty.

One embodiment, of the Stack→State Transform compiler is designed around one of the smallest computing devices available with a minimum footprint of 4 KB ROM and 256 bytes of RAM and using a very small RISC instruction set of 35 instructions. One important consequence of this minimalist implementation is that it is relatively easy for computing devices with larger footprints in terms of RAM, ROM and Instructions sets to imitate the smaller model. That is, it is the minimal footprint is typically a subset of the larger footprint devices making it easier for example to find an equivalent instruction or small number of equivalent instructions on a 200 instruction CISC computing device than it is the other way around.

An import consequence is that the computing model required by the minimal computing model is easily emulated by other computing devices. A device emulating the instruction set and computing model of the minimum footprint device is hence able to execute the Java Virtual Machine code with only a minimal performance hit enabling cross platform high performance execution. An important consequence is that all the tools and testing development is implemented only on the minimal footprint device and the other platforms are supported by the once-only implementation of the emulation transform along with the implementation of any of the device specific interfaces.

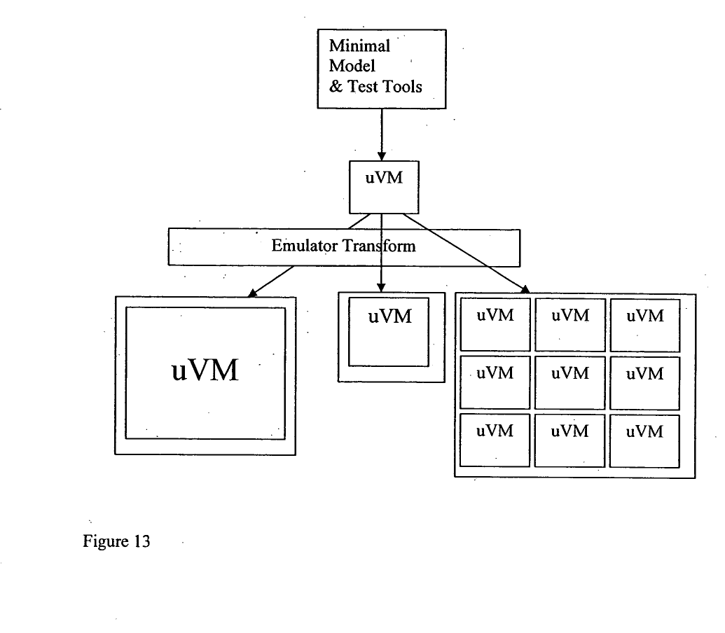

This technique is illustrated by the cross family execution of the inventive enhanced JVM compiler. Two supported platforms are the PICMICRO 16F and the PIC 18F architectures. The 16F family has 35 instructions while the 18F has 85 instructions. Future architectures including those from other vendors further illustrate the technique. Of further consequence is that a larger device may support more than one emulated model, thereby enabling more than one enhanced JVM to execute on the device. This is particularly true when the device implements the minimum device requirement in silicon creating the opportunity for building massively parallel java computing devices. See FIG. 13.

The above specification, examples and data provide a complete description of the manufacture and use of the composition of the invention. Since many embodiments of the invention can be made without departing from the spirit and scope of the invention, the invention resides in the claims hereinafter appended.

1. A method for optimizing the operation of a virtual machine, comprising:
precomputing a stack frame;
placing the stack frame in a known static location; and
in response to an access of the stack frame, providing the precomputed stack frame from the known static location.

2. A method for implementing a virtual machine, comprising:
determining a known static location for at least one stack register that is directly addressable in a memory;
placing a stack frame in the at least one stack register for the known static location, wherein at least one operand pre-computes at least one result for the stack frame in the at least one stack register; and
employing the at least one pre-computed result in the compiling of instructions for the virtual machine.

3. The method of claim 2, wherein generating the pre-computing further comprises generating inline code that directly addresses the at least one stack register.

4. The method of claim 2, wherein the pre-computing further comprises:
grouping a plurality of stack instructions; and
generating an inline code sequence that computes a result of the stack instructions.

5. The method of claim 4, further comprising recognizing a pattern of stack instructions.

6. The method of claim 2, further comprises:
copying a first stack frame to the known static location;
compressing the first stack frame; and
executing in a second stack frame.

7. The method of claim 2, further comprising:
if a frame cache is available, switching from a first stack frame to a second stack frame by changing a current bank of data memory without backing up the first stack frame; and
executing in the second frame.

8. The method of claim 7 wherein the frame cache is a pre-allocated frame on an alternative page.

9. The method of claim 2, further comprising:
executing a first thread in a frame page for the first thread; and
context-switching to a second thread by switching to a memory bank having a frame stack that contains a state of the second thread.

10. The method of claim 2, wherein the virtual machine operates on at least one of a personal computer and an embedded electronic device.

11. A compiler for implementing a virtual machine on an embedded device, comprising:
determining a known static location for at least one stack register that is directly addressable in a memory of the;
placing a stack frame in the at least one stack register for the known static location, wherein at least one operand pre-computes at least one result for the stack frame in the at least one stack register; and
compiling the at least one pre-computed result to execute the actions of the virtual machine.

12. The compiler of claim 11, wherein generating the pre-computing further comprises generating inline code that directly addresses the at least one stack register.

13. The compiler of claim 11, wherein the pre-computing further comprises:
grouping a plurality of stack instructions; and
generating an inline code sequence that computes a result of the stack instructions.

14. The compiler of claim 13, further comprising recognizing a pattern of stack instructions.

15. The compiler of claim 11, further comprises:
copying a first stack frame to the known static location;
compressing the first stack frame; and
executing in a second stack frame.

16. The compiler of claim 11, further comprising:
if a frame cache is available, switching from a first stack frame to a second stack frame by changing a current bank of data memory without backing up the first stack frame; and
executing in the second frame.

17. The compiler of claim 16, wherein the frame cache is a pre-allocated frame on an alternative page.

18. The compiler of claim 11, further comprising:
executing a first thread in a frame page for the first thread; and
context-switching to a second thread by switching to a memory bank having a frame stack that contains a state of the second thread.

19. The compiler of claim 11, wherein the virtual machine is at least one of a Java Virtual Machine and a .NET MSIL virtual machine.

20. The compiler of claim 11, wherein the embedded device is at least one of an eight bit microprocessor and a microcontroller.

21. A computer readable medium that includes instructions for performing actions that enable the implementation of a virtual machine, the actions comprising:
determining a known static location for at least one stack register that is directly addressable in a memory;
placing a stack frame in the at least one stack register for the known static location, wherein at least one operand pre-computes at least one result for the stack frame in the at least one stack register; and
employing the at least one pre-computed result in the compiling of instructions for the virtual machine.
